(19) United States
(12) Patent Application Publication
(10) Pub. No.: US 2019/0198284 A1
(43) Pub. Date: Jun. 27, 2019

(54) ELECTRON SOURCE AND ELECTRON BEAM IRRADIATION DEVICE

(71) Applicant: HITACHI HIGH-TECHNOLOGIES CORPORATION, Tokyo (JP)

(72) Inventors: Soichiro MATSUNAGA, Tokyo (JP); Yasunari SOHDA, Tokyo (JP); Souichi KATAGIRI, Tokyo (JP); Hajime KAWANO, Tokyo (JP); Takashi DOI, Tokyo (JP)

(73) Assignee: HITACHI HIGH-TECHNOLOGIES CORPORATION, Tokyo (JP)

(21) Appl. No.: 16/328,150

(22) PCT Filed: Sep. 6, 2016
(86) PCT No.: PCT/JP2016/076146

§ 371 Date: Feb. 25, 2019

(51) Int. Cl. H01J 37/073; H01J 37/244; H01J 37/28

(52) U.S. Cl. CPC H01J 37/073; H01J 37/244; H01J 37/28; H01J 2237/2809; H01J 2237/24485; H01J 2237/24578; H01J 2237/2448

(57) ABSTRACT

Provided is a high-brightness, high-current electron source including a wire-like member. The wire-like member has an electron emission plane at the tip of the wire-like member. The electron emission plane has a projectingly curved surface. At least the surface of the electron emission plane is formed of an amorphous material.

### TECHNICAL FIELD

The present invention relates to an electron source and an electron beam irradiation device.

### BACKGROUND ART

Scanning electron microscopes (SEMs), which are one of various electron beam irradiation devices, are widely used to visualize microstructures. In addition to morphological observation of metals and other materials and observation of microscopic shapes and forms of biological samples, the SEMs are used, for example, for dimensional inspection and defect inspection of microscopic semiconductor patterns. The SEMs perform a scan while irradiating a measurement sample with an electron beam, and acquire a scan image (SEM image) by detecting signal electrons (secondary electrons and backscattered electrons) emitted from the measurement sample.

Limits of microstructures visualizable by the above-mentioned SEM image depend on the spot diameter of an electron beam incident on a sample. When the SEMs are used, the size of a light source in the electron source affects a beam spot diameter. Therefore, for the SEMs for achieving high spatial resolution, an electron source having a small light source is used. As such an electron source, a field emission electron source is widely used.

For the field emission electron source, the tip of a monocrystalline metal is sharpened to approximately 0.1 μm. When a positive voltage for the electron source is applied to an electrode disposed to face the electron source, a strong electric field of approximately 1×10⁹ V/m concentrates at the tip of the electron source to emit electrons. This electron source is called a cold-field emitter (CFE).

A thermal field emission electron source is also widely used. The thermal field emission electron source acquires an electron beam by concurrently using heat and electric field. As the thermal field emission electron source, a surface diffusion electron source is commercialized. The surface diffusion electron source is such that the oxide or nitride of metal having a lower work function than the monocrystalline tip, such as Zr, Ti, Sc, Hf, or Ba, is subjected to approximate monatomic layer adsorption with respect to the surface of a monocrystalline tip formed of a refractory metal material such as W or Mo. Stable electron emission is achieved by heating this type of electron source to a temperature as high as 1500 to 1900 K, and applying a strong electric field of 5×10⁸ to 1.5×10⁹ V/m to the electron source. This type of electron source is called a Schottky electron source.

All electron sources are formed of a monocrystalline base material. The reason is that an electron emission plane can be limited to reduce the size of the light source by making use of difference in a crystal structure and the ease of electron emission (work function), which is dependent on a crystal plane of the crystal structure.

A technology disclosed, for example, in Patent Document makes it possible to achieve convergence to a nanosized electron beam by machining a protruding tip of an electron source tip formed of a conductive nonmetal material, such as diamond, into a curved surface, such as a spherical or conical surface.

### PRIOR ART DOCUMENT

### Patent Document

Patent Document 1: JP-2008-177017-A

### SUMMARY OF THE INVENTION

### Problem to be Solved by the Invention

The spatial resolution of the above-mentioned SEM image greatly depends on the performance of an electron beam incident on a sample. Characteristics of the electron beam, which are directly related to the performance of an electron microscope, include, for example, the current density per unit radiation solid angle (hereinafter referred to as the angular current density) and the size of an electron beam light source. When the angular current density is high, the current incident on the sample can be increased to obtain SEM images having a high signal-to-noise ratio. Further, high-speed imaging is achievable because it is possible to reduce the exposure time required to obtain SEM images having the same signal-to-noise ratio.

Meanwhile, when the size of the light source is small, the spot diameter of an electron beam incident on the sample can be reduced to obtain SEM images having a high spatial resolution. That is to say, it is preferable that an electron source having a high angular current density and a small-size light source be used to obtain high-quality SEM images. As the angular current density is a value proportional to the area of the light source, the performance of an electron source is often discussed based on brightness that is determined by dividing the angular current density by the area of the light source. Therefore, high-resolution SEMs adopt an electron source having high brightness.

High-brightness electron sources have been implemented by reducing the area of the light source. A certain technology for reducing the area of the light source uses a monocrystalline electron source. This technology is based on the fact that the ease of electron emission (work function) differs depending on the plane orientation of a crystal. This technology reduces the area of the light source by limiting the electron emission plane.

For example, the CFE generally uses the (310) plane of tungsten as the electron emission plane. The Schottky electron source uses the (100) plane of tungsten. As regards these electron sources, strong electron emission occurs only from a particular crystal plane. Therefore, electron emission occurs in a direction reflecting the symmetry of the crystal, and only an electron beam emitted from a particular plane can be acquired by limiting part of such electron emission by a diaphragm. Limiting the electron emission plane implements a light source of 3 to 5 nm for the CFE and a light source of 30 to 50 nm for the Schottky electron source.

The light source for the Schottky electron source is greater than the light source for the CFE because the former has a larger electron emission area. The (100) plane of several hundred nanometers is open at the tip apex of the Schottky electron source. The current density available from the Schottky electron source is higher than the current density available from the CFE. Therefore, the current incident on the sample can be increased.

It is known that a light source effective for a field emission electron source is smaller than the actual size of the electron emission plane. The reason is that, although the electron emission plane is planar, emitted electrons are accelerated by an electric field generated by an extraction electrode, and that, when viewed from the downstream side of the extraction electrode, the electron beam looks like being emitted from a light source disposed behind the electron emission plane and smaller than the electron emission plane. The light source effective for the field emission electron source is called a virtual source. The virtual sources for the CFE and Schottky electron source are schematically depicted in FIGS. 1A and 1B, respectively. The CFE depicted in FIG. 1A includes a tungsten (310) monocrystalline wire 101 having a sharpened tip, and the (310) plane acts as an electron emission plane 102. Reference character 103 denotes a typical electron trajectory of electrons emitted from the electron source, reference character 104 denotes a virtual trajectory obtained by armoring the electron trajectory 103, and reference character 105 denotes a virtual source. The Schottky electron source depicted in FIG. 1B includes a tungsten (100) monocrystalline wire 106 having a sharpened tip, and the (100) plane acts as an electron emission plane 107. Reference character 108 denotes a typical electron trajectory of electrons emitted from the electron source, reference character 109 denotes a virtual trajectory obtained by armoring the electron trajectory 108, and reference character 110 denotes a virtual source. A field emission electron source using a monocrystalline plane as the electron emission plane 102 and 107 has a problem in which the virtual source is large when the electron emission plane is large.

The technology disclosed in Patent Document 1 provides an electron source formed of diamond, that is, non-metallic monocrystalline, with a tip having a curved surface in order to improve tip-machining characteristics. However, such machining is not performed for the purpose of reducing the size of the virtual source. Therefore, even when the tip of a crystalline material is machined into a curved surface, such as a spherical or conical surface, a stable crystal plane is constantly formed on the curved surface. Consequently, the technology disclosed in Patent Document 1 does not solve the problem described in the present application.

An object of the present invention is to provide a high-brightness, high-current electron source and a high-spatial-resolution electron beam irradiation device.

### Means for Solving the Problem

According to an aspect of the present invention, there is provided an electron source including a wire-like member. The wire-like member has an electron emission plane at the tip of the wire-like member. The electron emission plane has a projectingly curved surface. At least the surface of the electron emission plane is formed of an amorphous material.

According to another aspect of the present invention, there is provided an electron beam irradiation device including an electron source and an electron optical system. The electron source includes a wire-like base material and a surface material. The wire-like base material is formed of a conductive material. The surface material is formed of an amorphous material at the tip of the base material, and used as an electron emission plane having a projectingly curved surface. The electron optical system irradiates a sample with primary electrons extracted from the electron source.

According to still another aspect of the present invention, there is provided an electron beam irradiation device including an electron source and an electron optical system. The electron source includes a wire-like member. The wire-like member is formed of a conductive amorphous material. The tip of the wire-like member acts as an electron emission plane having a projectingly curved surface. The electron optical system irradiates a sample with primary electrons extracted from the electron source.

### Effect of the Invention

The present invention provides a high-brightness, high-current electron source and a high-spatial-resolution electron beam irradiation device.

### BRIEF DESCRIPTION OF THE DRAWINGS

FIG. 1A is a cross-sectional view illustrating the structure and virtual source of a CFE.

FIG. 1B is a cross-sectional view illustrating the structure and virtual source of a Schottky electron source.

FIG. 2 is a cross-sectional view illustrating the structure of the tip of an electron source according to a first embodiment.

FIG. 3 is a cross-sectional view illustrating an electron emission plane and virtual source of the electron source according to the first embodiment.

FIG. 4A is a schematic diagram illustrating an electron emission pattern of the CFE.

FIG. 4B is a schematic diagram illustrating the electron emission pattern of the Schottky electron source.

FIG. 4C is a schematic diagram illustrating the electron emission pattern of the electron source according to the first embodiment.

FIG. 5 is a cross-sectional view illustrating a configuration of the electron source according to a second embodiment.

FIG. 6A is a cross-sectional view illustrating how the virtual source of the electron source according to a third embodiment is affected by the shape (spherical) of the tip of the electron source and the shape (spherical) of an extraction electrode.

FIG. 6B is a cross-sectional view illustrating how the virtual source of the electron source according to the third embodiment is affected by the shape (spherical) of the tip of the electron source and the shape (planar) of the extraction electrode.

FIG. 6C is a cross-sectional view illustrating how the virtual source of the electron source according to the third embodiment is affected by the shape (aspherical) of the tip of the electron source and the shape (planar) of the extraction electrode.

FIG. 7 is a cross-sectional view illustrating a configuration of the electron source according to a fourth embodiment.

FIG. 8 is a cross-sectional view illustrating a configuration of the electron source according to a fifth embodiment.

FIG. 9 is a cross-sectional view illustrating a configuration of an electron beam irradiation device (a SEM) according to a sixth embodiment.

FIG. 10 is a cross-sectional view illustrating a configuration of the electron beam irradiation device (a SEM with a built-in electron energy measurement device) according to a seventh embodiment.

FIG. 11 is a cross-sectional view illustrating another configuration of the electron beam irradiation device (a SEM with a built-in electron beam diffraction pattern measurement device) according to the seventh embodiment.

### MODE FOR CARRYING OUT THE INVENTION

The inventors and the like studied a method of providing a high-brightness, high-current electron source, that is, a method of reducing the size of a virtual source and increasing the angular current density. As a result, it was found that the method is made implementable by adopting a configuration including a base material and a surface material. The base material is formed of a conductive material. The surface material is formed of an amorphous material disposed to cover the tip of the base material and is provided with a region having a curved surface and acting as an electron emission plane. When the electron emission plane is a curved surface, a virtual trajectory converges to one point. This makes it possible to reduce the size of the virtual source. Further, when the surface material is formed of an amorphous material, it is possible to obtain a curved electron emission plane and suppress intensity distribution irregularity of electron emission. That is to say, even when the angular current density is high, the virtual source is small in size. It signifies that a high-brightness, high-current electron source can be obtained. Using such an electron source makes it possible to obtain an electron microscope image having a high signal-to-noise ratio and a high spatial resolution.

Embodiments of the present invention will now be described with reference to the accompanying drawings. Like elements are designated by like reference characters.

### First Embodiment

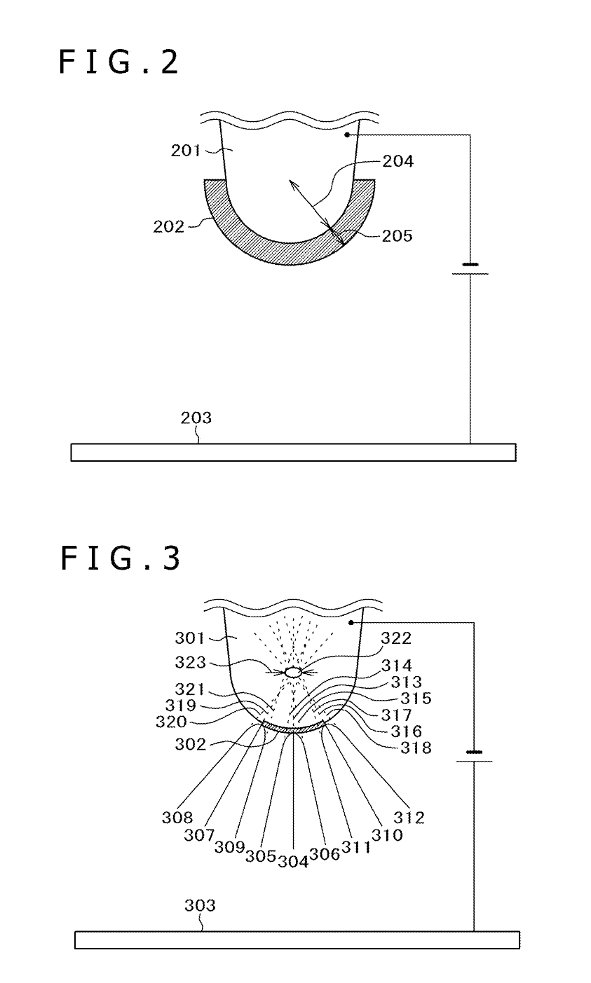

A first embodiment of the present invention is described below with reference to the accompanying drawings. FIG. 2 is a cross-sectional view illustrating the structure of the tip of an electron source according to the first embodiment. A tungsten wire 201 is adopted as the main body (base material) of the electron source. The tip of the tungsten wire 201 is sharpened by electrochemical etching, and the curvature radius 204 of the tip is shaped into a curved surface (a projectingly curved surface, for example, a spherical surface) by heating. The tungsten wire 201 may be formed of a monocrystalline or polycrystalline substance that is used in a conventional CFE and Schottky electron source.

The tip of the electron source base material is coated by vapor-depositing amorphous carbon 202 onto the surface of the base material (wire) 201 of the electron source. The thickness 205 of the applied coating is 0.01 μm or greater so that the crystal structure of the surface remains unaffected. An extraction electrode 203 is installed to face the electron source. Although the extraction electrode depicted in FIG. 2 is shaped like a plain plate, the extraction electrode may be bored to acquire a current. When the electron source and the extraction electrode are installed in a vacuum and a voltage positive with respect to the electron source is applied to the extraction electrode, an electric field concentrates on the sharpened tip apex of the electron source to emit electrons.

Although the present embodiment adopts tungsten that is used as a material for a conventional high-brightness electron source, the tungsten may be substituted by an electrically conductive substance. The amorphous carbon may be deposited by using a sputter or ion beam deposition method. The curved surface of the tip of the electron source may alternatively be shaped by an ion beam. The electron source need not always be entirely coated with the amorphous carbon. Coating only an electron emission section will suffice. Although the present embodiment uses carbon as an amorphous substance for coating, the carbon may be substituted by a carbon compound, a group 14 element such as silicon, a group 13-15 compound, glass, or other material capable of maintaining an amorphous state at room temperature. However, when a non-conductive material is used, it needs to be thin enough to permit electron tunneling.

Although the coating thickness is 0.01 μm in the present embodiment, a coating thickness of 1 μm or less is feasible. The reason will now be described with reference to FIG. 2. FIG. is a schematic diagram illustrating the tip of the electron source. FIG. 2 deals with a case where the base material 201 is coated with the amorphous material 202. When the curvature radius 204 of the tip of the base material is R, and the film thickness 205 of the coating is T, the curvature radius of a coating surface acting as an electron emission plane can be expressed by (R+T).

The strength of an electric field generated at the tip of the electron source is inversely proportional to the above-mentioned curvature radius (R+T) and is proportional to an extraction voltage. That is to say, when an electric field having the same strength as in a case where no coating is applied is to be generated at the tip of the electron source that is coated with an amorphous material, an extraction voltage higher than when no coating is applied needs to be applied to the extraction electrode 203.

However, when the extraction voltage is raised, a discharge is highly likely to occur in an electron gun. In a case where a clean surface of tungsten is used for field emission, electrons are emitted by applying an extraction voltage of approximately 4 kV to an electron source with a tip having a curvature radius R=0.1 μm. When the extraction voltage for generating an electric field having approximately the same strength for the electron source according to the present embodiment is to be reduced to 50 kV or lower, R needs to be 1 μm or less. However, the intended effects are achieved as far as the thickness of an amorphous coating is 1 nm to 5 μm. A practical range of the amorphous coating thickness is 1 nm to 1 μm, and a suitable range is 1 nm to 0.1 μm.

The reason why coating with amorphous carbon is necessary will now be described. The virtual source can be reduced in size by curving the electron emission plane. However, shaping the tip of the electron source into a curved surface in a simple manner is insufficient. The reason is that even if the tip of an amorphous substance used as a field emission electron source, such as metal or diamond, is shaped into a spherical surface, a stable crystal plane is formed over the spherical surface. That is to say, the surface of the electron source is configured as a crystal plane aggregate having a size of approximately several tens of nanometers. In this instance, the work function depends on the orientation of the crystal plane. Therefore, electron emission is likely to occur only in a particular direction so that the intensity distribution of an electron beam is not uniform. If the intensity distribution is not uniform, electron emission density decreases so that high brightness cannot be achieved. Under such circumstances, the electron emission plane is formed of a non-crystalline substance, that is, an amorphous substance. This reduces the non-uniformity of electron beam emission, which is dependent on the orientation of the crystal plane.

When the spatial distribution pattern of electron emission is measured, it is found that electron emission is no longer dependent on crystal orientation. The spatial distribution pattern can be obtained by installing a fluorescent screen downstream of the extraction electrode and capturing an image of the fluorescent screen with a digital camera.

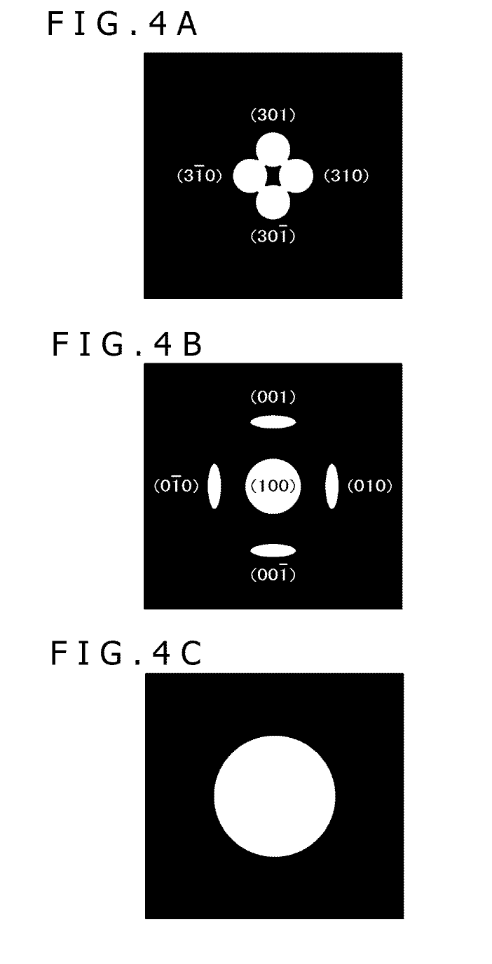

When a conventional high-brightness electron source, such as a CFE or a Schottky electron source, is used, electrons are selectively emitted from the (310) or (100) plane of tungsten so that an electron emission pattern corresponding to such a crystal plane is obtained as depicted in FIGS. 4A and 4B. However, when an amorphous material is used for coating, an isotropic electron emission pattern is obtained because there is no plane orientation dependency as depicted in FIG. 4C.

The relationship between the virtual source and typical electron trajectories of electrons emitted from the above-mentioned electron source will now be described with reference to FIG. 3. The base material 301 of the electron source is coated with an amorphous material 302, and a voltage is applied to an extraction electrode 303 to emit electrons. Typical electron trajectories among trajectories of electrons emitted from the electron source are designated by reference characters 304 to 312 in FIG. 3. A trajectory 304 is a trajectory of electrons emitted in the normal direction from the center of the electron emission plane toward the surface of the electron source. A trajectory 305 is a trajectory of electrons emitted in the tangential direction from the center of the electron emission plane toward the surface of the electron source. A trajectory 306 is a trajectory of electrons emitted in the same tangential direction as the trajectory 305 but in a direction opposite from the trajectory 305. A trajectory 307 is a trajectory of electrons emitted in the normal direction from an end of the electron emission plane toward the surface of the electron source. A trajectory 308 is a trajectory of electrons emitted in the normal direction from an end of the electron emission plane toward the surface of the electron source. A trajectory 309 is a trajectory of electrons emitted in the same tangential direction as the trajectory 308 but in a direction opposite from the trajectory 308. Trajectories 310, 311, and 312 are trajectories of electrons emitted from an end of the electron emission plane that is an end opposite from the trajectories 307, 308, and 309, respectively. Broken lines designated by reference characters 313 to 321 represent virtual trajectories that are respectively obtained from the electron trajectories 304 to 312 by armoring the electron trajectories. Reference character 322 depicts a plane to which the virtual trajectories of electrons emitted from the electron emission plane converge and the size 323 of a convergence spot on such a convergence plane. This acts as a virtual source for the field emission electron source.

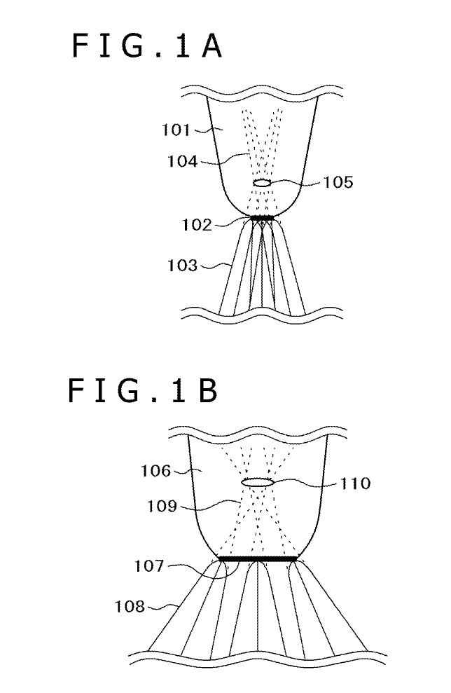

Even if the electron emission plane is shaped into a curved surface to increase the angular current density in a case where the electron source is configured as depicted in FIG. 2, the size of the virtual source can be reduced to no more than 50% of the size of the virtual source of a Schottky electron source that uses electron emission from a particular crystal plane of a tungsten monocrystal depicted in FIG. 1B. As a result, a high-brightness, high-current electron source is obtained.

As described above, the present embodiment provides a high-brightness, high-current electron source.

### Second Embodiment

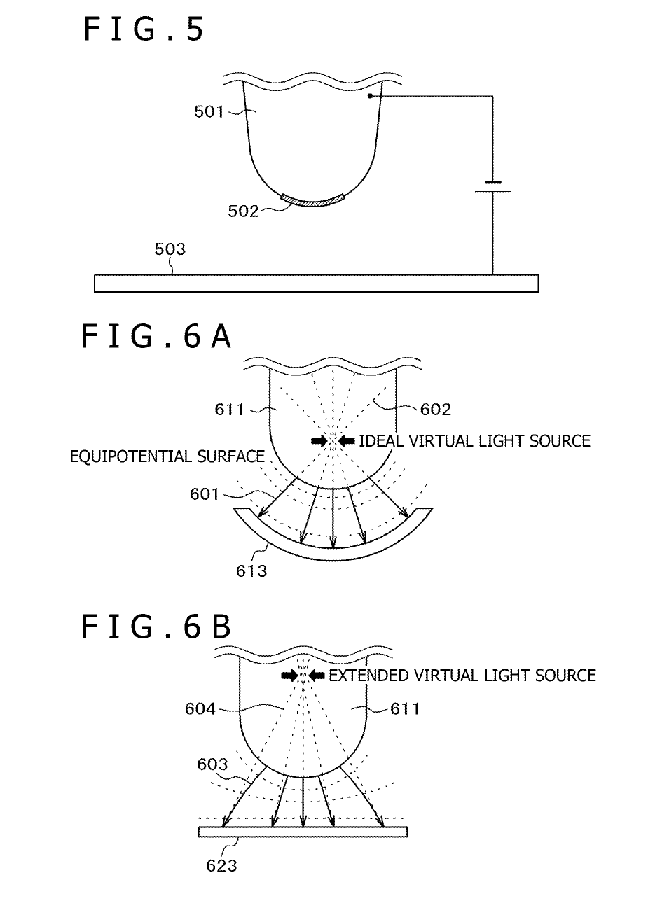

The electron source according to a second embodiment of the present invention will now be described with reference to FIG. 5. Matters described in conjunction with the first embodiment and not described in conjunction with the second embodiment are applicable to the second embodiment unless otherwise noted. The second embodiment will be described with reference to an example in which amorphous coating is achieved with increased ease.

FIG. 5 illustrates the structure of the electron source according to the second embodiment. As is the case with the first embodiment, the main body of the electron source is formed of tungsten wire 501 that is obtained by sharpening the tip of the tungsten wire 501 by electrochemical etching and performing heat treatment to shape the tip into a curved surface (spherical). The surface of the electron source is coated with a fluid carbon-containing compound (organic polymer) 502. In the second embodiment, the surface of the electron source is directly coated with a carbon-containing compound. However, the surface of the electron source may be coated with a carbon-containing compound dissolved or suspended into a solvent. The amorphous carbon coating described in conjunction with the first embodiment is easily implemented by coating the surface of the electron source with an organic substance and heating a coating agent for carbonization.

Next, as is the case with the first embodiment, an extraction electrode 503 is installed so as to face the electron source in order to extract electrons. The extraction electrode depicted in FIG. 5 is shaped like a plain plate. However, the extraction electrode may be bored to acquire a current.

As described above, the second embodiment provides the same advantageous effects as the first embodiment. Additionally, using the fluid carbon-containing compound as the coating agent makes it easy to control the film thickness and uniformity of the coating. Moreover, heating the coating agent containing an organic substance for carbonization makes it easy to implement the amorphous carbon coating.

### Third Embodiment

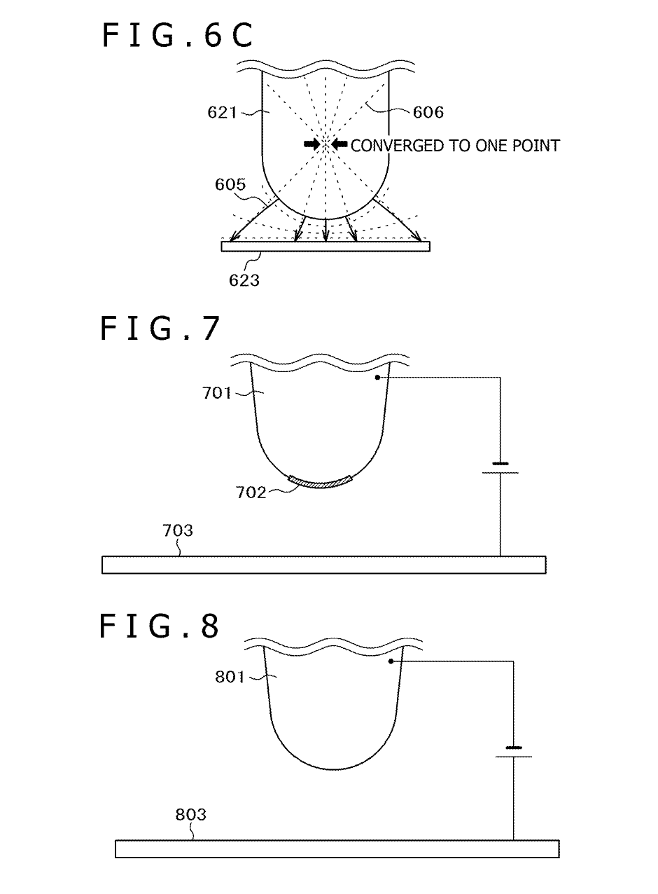

The electron source according to a third embodiment of the present invention will now be described with reference to FIGS. 6A to 6C. Matters described in conjunction with the first or second embodiment and not described in conjunction with the third embodiment are applicable to the third embodiment unless otherwise noted. The third embodiment will be described with reference to an example in which the advantageous effects of the first embodiment are enhanced when the field emission electron source is used for an electron gun.

FIGS. 6A to 6C are schematic cross-sectional views illustrating an electric potential distribution, a trajectory of emitted electrons, a virtual trajectory, and a virtual source in a case where the surface shape of the electron source and the extraction electrode are changed. FIG. 6A illustrates a case where electrons are extracted from an electron source with a base material 611 having a spherical tip surface by an extraction electrode 613 having a spherical shape concentric with the spherical tip surface. The electric potential distribution is in spherical symmetry, and the electrons are emitted in a direction 601 passing through a spherical center. In this instance, a virtual trajectory 602 converges to the spherical center. Therefore, the virtual source turns into a single point at the spherical center. Ideally, the resulting brightness is infinite.

Meanwhile, an electron gun in an actual electron beam irradiation device emits an electron beam in one direction. Therefore, the extraction electrode has a non-spherical surface in most cases. The third embodiment will be described with reference to a case where the extraction electrode has a planar surface as an example in which the surface of the extraction electrode is not spherical. When an extraction electrode 623 has a planar surface as depicted in FIG. 6B, electrons are attracted toward the extraction electrode 623. Therefore, an electron trajectory 603 is bent toward the extraction electrode 623. As a result, a virtual trajectory 604 does not converge to one point as depicted in FIG. 6B so that a light source has a finite size.

In order to reduce the size of the virtual source by suppressing the extension of the virtual trajectory even when a planar electrode is used for extraction, the present embodiment changes the shape of the electron source from the spherical surface. More specifically, as depicted in FIG. 6C, the tip is shaped so that the curvature radius of the tip of the base material 621 forms an increasingly large curved surface with an increase in the distance from the center of the electron beam to be extracted (with an increase in the distance from the center of the electron emission plane). Referring to FIG. 6B, when the electron emission plane is a spherical surface, the virtual trajectory converges to a point increasingly behind the electron source in the case of electrons increasingly distant from the center of the electron beam. The electron emission plane is shaped in a direction increasingly perpendicular to the extraction electrode with an increase in the distance from the center of the electron beam. This changes an electron trajectory 605 that is positioned apart from the center of the emitted electron beam. Thus, the resulting virtual trajectory 606 increasingly approaches the front of the electron source. Consequently, the size of the virtual source can be reduced as compared with the configuration depicted in FIG. 6B (the configuration of the first embodiment). This enhances the advantageous effects provided by a high current and high brightness.

Even when the extraction electrode is not spherical in shape, the present embodiment reduces the size of the virtual source. The above-mentioned advantageous effects remain unchanged even when such an extraction electrode is bored to acquire a current.

As described above, the third embodiment provides the same advantageous effects as the first embodiment. Additionally, as the tip of the base material is shaped so that the curvature radius of the tip forms an increasingly large curved surface with an increase in the distance from the center of the electron emission plane, the size of the virtual source can be further reduced.

### Fourth Embodiment

The electron source according to a fourth embodiment of the present invention will now be described with reference to FIG. 7. Matters described in conjunction with any one of the first to third embodiments and not described in conjunction with the fourth embodiment are applicable to the fourth embodiment unless otherwise noted. The fourth embodiment will be described with reference to an example in which the shape of the tip of the electron source is stabilized in order to emit electrons in a stable manner. The tip of the field emission electron source may be deformed by a temperature rise due to a strong electric field or electron emission or by high-temperature cleaning of the surface of the electron source. When the tip is deformed, the degree of electric field concentration changes to change the current to be released. Therefore, the deformation of the tip of the electron source needs to be suppressed in order to emit electrons in a stable manner.

FIG. 7 illustrates the structure of the electron source according to the fourth embodiment. A molybdenum wire 701 is used as the base material for the electron source. The molybdenum wire 701 is a high-melting point metal having a tip that is sharpened and shaped into a spherical surface (semi-spherical) by ion-beam machining. Although the present embodiment uses molybdenum as the high-melting point metal, an alternative is to use a metal having a melting point of 1500 K or higher, such as rhenium, tantalum, niobium, or hafnium. Further, high-melting point metal compounds based on the above-mentioned conductive metals may also be used. Using a high-melting point metal or its compound as the base material for the electron source makes it possible to achieve stable electron emission while suppressing the deformation caused by an electric field or heat.

As is the case with the first embodiment, the surface of the base material is coated with amorphous carbon 702, and an extraction electrode 703 is installed so as to face the electron source. The extraction electrode depicted in FIG. 7 is shaped like a plain plate. However, the extraction electrode may be bored to acquire a current. The fourth embodiment is the same as the first embodiment except that the electron source according to the fourth embodiment has a different configuration (wire material). Although the fourth embodiment uses amorphous carbon for the main body of the electron source, the material for the main body may be substituted by a group 14 element such as silicon, a group 13-15 compound, organic polymer, glass, or other material capable of maintaining an amorphous state at room temperature, as is the case with the first embodiment. Further, a carbon-containing compound may be used for coating, as is the case with the second embodiment. However, when a non-conductive material is used, it needs to be thin enough to permit electron tunneling.

As described above, the fourth embodiment provides the same advantageous effects as the first embodiment. Additionally, using a high-melting point metal or its compound as the base material for the electron source suppresses the deformation of the tip of the electron source.

### Fifth Embodiment

The electron source according to a fifth embodiment of the present invention will now be described with reference to FIG. 8. Matters described in conjunction with any one of the first to fourth embodiments and not described in conjunction with the fifth embodiment are applicable to the fifth embodiment unless otherwise noted. The fifth embodiment will be described with reference to an example in which the necessity of coating with an amorphous material is eliminated in order to facilitate the manufacture of the electron source.

FIG. 8 illustrates the structure of the electron source according to the fifth embodiment. Amorphous silicon shaped like a wire is sharpened (semi-spherical) by chemical etching and used as a main body (wire member) 801 of the electron source. As the wire member itself is amorphous, no coating is needed. This provides an advantage in that a process of manufacturing the electron emission plane having a curved surface and formed of an amorphous material can be simplified. Another advantage is that the structure of the electron source can be manufactured by using a lithographic technique for manufacturing a silicon semiconductor. Using the lithographic technique makes it possible to manufacture a structure for forming an electron source array or a structure for integrating the electron source with the extraction electrode.

Next, an extraction electrode 803 is installed so as to face the electron source, as is the case with the first embodiment. The extraction electrode 803 depicted in FIG. 8 is shaped like a plain plate. However, the extraction electrode may be bored to acquire a current. The fifth embodiment is the same as the first embodiment except that the electron source according to the fifth embodiment has a different configuration (base material). Although the fifth embodiment uses amorphous silicon for the main body of the electron source, the material for the main body may be substituted, for example, by a group 14 element such as carbon, a group 13-15 compound, a carbon-containing compound, or glass that is conductive at room temperature.

As described above, the fifth embodiment provides the same advantageous effects as the first embodiment. Additionally, as an amorphous material is used as the base material, the base material need not be coated with an amorphous material. This simplifies a manufacturing process.

### Sixth Embodiment

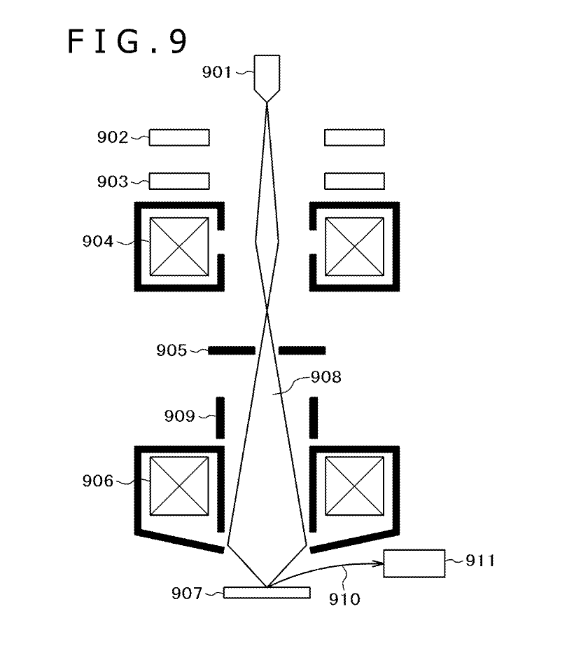

An electron beam irradiation device according to a sixth embodiment of the present invention will now be described with reference to FIG. 9. Matters described in conjunction with any one of the first to fifth embodiments and not described in conjunction with the sixth embodiment are applicable to the sixth embodiment unless otherwise noted. The sixth embodiment will be described with reference to an example of a SEM in which the electron source described in conjunction with the first embodiment is mounted.

FIG. 9 is a cross-sectional view illustrating a configuration of an electron microscope (SEM) according to the sixth embodiment. The SEM includes an electron source 901, an extraction electrode 902, an accelerating electrode 903, a condenser lens 904, a diaphragm 905, a scanning deflector 909, an objective lens 906, and a detector 911. The electron source 901 and the extraction electrode 902 have the same configurations as depicted in FIG. 2, which illustrates the first embodiment. The accelerating electrode 903 is disposed downstream of the electron source 901 and the extraction electrode 902. The condenser lens 904 and the diaphragm 905 are disposed downstream of the accelerating electrode 903. The condenser lens 904 converges an electron beam (primary electron beam) 908. The diaphragm 905 limits an acceptance angle. The scanning deflector 909 moves an electron beam for scanning purposes. The objective lens 906 converges the primary electron beam 908 to a measurement sample 907. The detector 911 detects secondary electrons 910 that are generated when the primary electron beam 908 is emitted.

The electron beam (primary electron beam) 908 extracted from the electron source 901 is converged to the measurement sample 907 by using the objective lens 906. A SEM image is obtained by scanning the measurement sample with the converged primary electron beam 908 through the use of the scanning deflector 909 and detecting the generated secondary electrons 910 with the detector 911. The sixth embodiment uses the electron source that is described in conjunction with the first embodiment. Alternatively, however, the electron source described in conjunction with any one of the second to fifth embodiments may be used.

As the dimensions of the virtual source for the electron source can be decreased, the spot diameter of the electron beam to be emitted onto the measurement sample can be decreased. Therefore, when the measurement sample is observed with the SEM depicted in FIG. 9, it is found that a SEM image having a high spatial resolution is obtained. Further, as the angular current density can be increased, the current to be incident on the measurement sample can be increased. Therefore, a SEM image having a high signal-to-noise ratio (SNR) is obtained. Consequently, a SEM image having a high signal-to-noise ratio (SNR) and a high spatial resolution is obtained. Moreover, increasing the current density makes it possible to achieve imaging at a higher speed than in the past. Therefore, the imaging time required for obtaining SEM images having the same SNR can be reduced. This makes it possible to achieve high-speed imaging. As a result, high-throughput, high-spatial-resolution SEM images can be obtained.

As described above, the sixth embodiment provides an electron beam irradiation device having a high spatial resolution. Further, as the current to be incident on a sample can be increased, SEM images having a high SNR and a high spatial resolution can be obtained. Moreover, high-throughput and high-spatial-resolution SEM images can be obtained.

### Seventh Embodiment

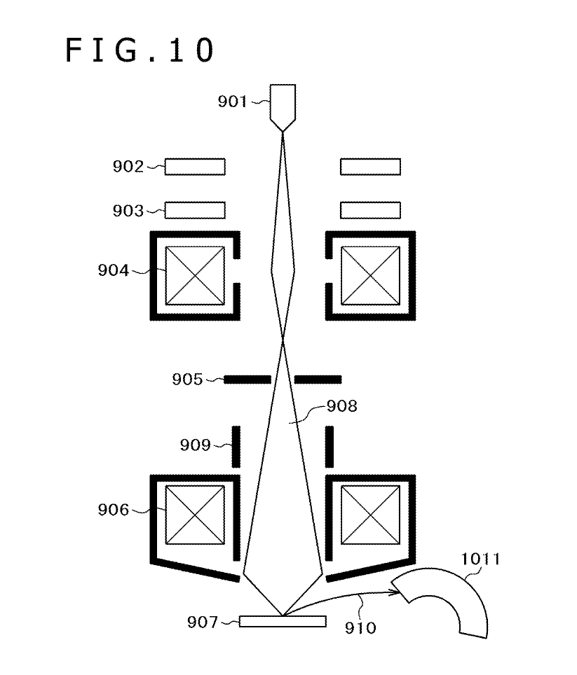

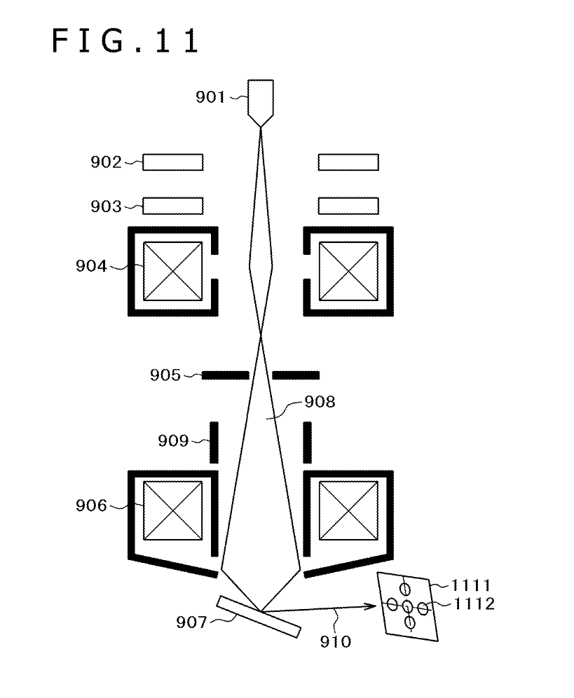

The electron beam irradiation device according to a seventh embodiment of the present invention will now be described with reference to FIGS. 10 and 11. Matters described in conjunction with any one of the first to sixth embodiments and not described in conjunction with the seventh embodiment are applicable to the seventh embodiment unless otherwise noted. The seventh embodiment will be described with reference to an example in which an electron energy measurement device or an electron beam diffraction pattern measurement device is mounted in the electron beam irradiation device having the electron source described in conjunction with the first embodiment.

FIG. 10 is a cross-sectional view illustrating a configuration of a SEM having an electron energy measurement device in accordance with the seventh embodiment. The seventh embodiment is the same as the sixth embodiment in basic configuration for irradiating a sample with an electron beam. The electron source 901, the extraction electrode 902, the accelerating electrode 903, the condenser lens 904, the diaphragm 905 for limiting the acceptance angle, and the objective lens 906, which have the same configuration as those depicted in FIG. 2 illustrating the first embodiment, are used to converge the primary electron beam 908 to the measurement sample 907. The scanning deflector 909 is used to scan the measurement sample with the converged primary electron beam 908, and the energy distribution of the generated secondary electrons 910 are measured with a spectrometer 1011. An Auger electron spectrometer or an electron beam energy loss spectrometer may be used as the spectrometer. As high spatial resolution is achieved by using the SEM having an electron energy measurement device depicted in FIG. 10, electron energy analysis of a local area can be made. Additionally, such analysis can be made at a high SNR. Further, high-speed measurements can be made. Furthermore, electron beam applied analysis can be made at a high SNR and at a high spatial resolution. Moreover, analysis can be made at a high measurement speed (a high throughput) and at a high spatial resolution. This reduces the time required for analysis to ¼.

FIG. 11 is a cross-sectional view illustrating a configuration of the SEM having an electron beam diffraction pattern measurement device in accordance with the seventh embodiment. The seventh embodiment is the same as the sixth embodiment in basic configuration for irradiating a sample with an electron beam. The electron source 901, the extraction electrode 902, the accelerating electrode 903, the condenser lens 904, the diaphragm 905 for limiting the acceptance angle, and the objective lens 906, which have the same configuration as those depicted in FIG. 2 illustrating the first embodiment, are used to converge the primary electron beam 908 to the measurement sample 907. The scanning deflector 909 is used to scan the measurement sample with the converged primary electron beam 908, and the interference pattern 1112 of the generated secondary electrons 910 are measured with two-dimensionally disposed detectors 1111. An electron backscatter diffraction device may be used as the detectors. Although the electron source described in conjunction with the first embodiment is used in the seventh embodiment, the electron source described in conjunction with any one of the second to fifth embodiments may alternatively be used. As high spatial resolution is achieved by using the SEM having an electron beam diffraction pattern measurement device depicted in FIG. 11, electron diffraction pattern analysis of a local area can be made. Additionally, such analysis can be made at a high SNR. Further, high-speed measurements can be made. Furthermore, electron beam applied analysis can be made at a high SNR and at a high spatial resolution. Moreover, analysis can be made at a high measurement speed (a high throughput) and at a high spatial resolution. This reduces the time required for analysis to ¼.

As described above, the seventh embodiment provides an electron beam irradiation device having a high spatial resolution. Further, as the current to be incident on a sample can be increased, analysis can be made at a high SNR and at a high spatial resolution. Moreover, analysis can be made at a high measurement speed and at a high spatial resolution.

The present invention is not limited to the foregoing embodiments, but includes various modifications. For example, the foregoing embodiments are described in detail in order to facilitate the understanding of the present invention. The present invention is not necessarily limited to a configuration that includes all the above-described elements. Further, some elements of a certain embodiment may be replaced by elements of another embodiment, and elements of a certain embodiment may be added to the elements of another embodiment. Furthermore, some elements of each embodiment may be subjected to the addition of other elements, deleted, or replaced by other elements.

### DESCRIPTION OF REFERENCE CHARACTERS

101: Sharpened tungsten (310) monocrystalline wire
102: (310) plane acting as electron emission plane
103: Typical electron trajectory of electrons emitted from electron source
104: Virtual trajectory obtained by armoring electron trajectory
103
105: Virtual source
106: Sharpened tungsten (100) monocrystalline wire
107: (100) plane acting as electron emission plane
108: Typical electron trajectory of electrons emitted from electron source
109: Virtual trajectory obtained by armoring electron trajectory 108
110: Virtual source
201: Sharpened tungsten wire
202: Amorphous carbon
203: Extraction electrode
204: Tip curvature radius of tungsten wire
205: Film thickness of amorphous carbon
301: Sharpened tungsten wire
302: Amorphous material
303: Extraction electrode
304-312: Typical trajectory of electrons emitted from electron source
313-321: Virtual trajectory obtained from electron trajectories
304 to 312
322: Virtual source (convergence point of virtual trajectories)
323: Size of virtual source
501: Sharpened tungsten wire
502: Organic polymer
503: Extraction electrode
601: Electron trajectory
602: Virtual trajectory
603: Electron trajectory
604: Virtual trajectory
605: Electron trajectory
606: Virtual trajectory
611: Base material
613: Extraction electrode
621: Base material
623: Extraction electrode
701: Sharpened molybdenum wire
702: Amorphous carbon
703: Extraction electrode
801: Sharpened amorphous silicon wire
803: Extraction electrode
901: Electron source described in conjunction with first embodiment
902: Extraction electrode
903: Accelerating electrode
904: Condenser lens
905: Diaphragm
906: Objective lens
907: Measurement sample
908: Converged primary electrons
909: Scanning deflector
910: Generated secondary electrons
911: Detector
1011: Energy spectrometer
1111: Two-dimensionally disposed electron detectors
1112: Interference pattern

1. An electron beam irradiation device comprising:
an electron source including a wire-like base material and a surface material, the wire-like base material being formed of a conductive material, the surface material being formed of an amorphous material at a tip of the base material and used as an electron emission plane having a projectingly curved surface; and
an electron optical system that irradiates a sample with primary electrons extracted from the electron source.

2. The electron beam irradiation device according to claim 1, wherein
the surface material has a film thickness of 1 nm or more and not more than 5 μm.

3. The electron beam irradiation device according to claim 1, wherein
the surface material is formed of carbon or silicon.

4. The electron beam irradiation device according to claim 1, wherein
the surface material is formed of a carbon-containing compound.

5. The electron beam irradiation device according to claim 1, wherein
the electron emission plane having a projectingly curved surface is configured such that a curvature radius of the projectingly curved surface increases with an increase in a distance from a center of the electron emission plane.

6. The electron beam irradiation device according to claim 1, wherein
the base material is a metal having a melting point of 1500° C. or higher.

7. The electron beam irradiation device according to claim 1, wherein
the amorphous material is formed of a group 14 element, a carbon-containing compound, a compound of a group 13 element and a group 15 element, or glass.

8. The electron beam irradiation device according to claim 1, further comprising:
a detector for detecting secondary electrons that are generated when the sample is irradiated with the primary electrons.

9. The electron beam irradiation device according to claim 1, further comprising:
a spectrometer for analyzing energy of secondary electrons that are generated when the sample is irradiated with the primary electrons.

10. The electron beam irradiation device according to claim 1, further comprising:
a detector for measuring a diffraction pattern of secondary electrons that are generated when the sample is irradiated with the primary electrons.

11. An electron beam irradiation device comprising:
an electron source including a wire-like member that is formed of a conductive amorphous material, a tip of the wire-like member acting as an electron emission plane having a projectingly curved surface; and
an electron optical system that irradiates a sample with primary electrons extracted from the electron source.

12. The electron beam irradiation device according to claim 11, wherein
the electron emission plane having a projectingly curved surface is configured such that a curvature radius of the projectingly curved surface increases with an increase in a distance from a center of the electron emission plane.

13. The electron beam irradiation device according to claim 11, wherein
the amorphous material is formed of a group 14 element, a carbon-containing compound, a compound of a group 13 element and a group 15 element, or glass.

14. The electron beam irradiation device according to claim 11, further comprising:
a detector for detecting secondary electrons that are generated when the sample is irradiated with the primary electrons.

15. The electron beam irradiation device according to claim 11, further comprising:
a spectrometer for analyzing energy of secondary electrons that are generated when the sample is irradiated with the primary electrons.

16. The electron beam irradiation device according to claim 11, further comprising:
a detector for measuring a diffraction pattern of secondary electrons that are generated when the sample is irradiated with the primary electrons.

17. An electron source including:
a wire-like member that has an electron emission plane having a projectingly curved surface at a tip of the wire-like member, and
at least a surface of the electron emission plane being formed of an amorphous material.

18. The electron source according to claim 17, wherein
the wire-like member includes a base material and a surface material, the base material being formed of a conductive material, the surface material being formed of an amorphous material on the electron emission plane, the amorphous material having a film thickness of 1 nm or more and not more than 5 μm.

19. The electron source according to claim 17, wherein
the electron emission plane having a projectingly curved surface is configured such that a curvature radius of the projectingly curved surface increases with an increase in a distance from a center of the electron emission plane.

20. The electron source according to claim 17, wherein
the amorphous material is formed of a group 14 element, a carbon-containing compound, a compound of a group 13 element and a group 15 element, or glass.
